(19) United States
(12) Patent Application Publication
(10) Pub. No.: US 2010/0171215 A1
(43) Pub. Date: Jul. 8, 2010

(54) Method of Producing Optoelectronic Components and Optoelectronic Component

(76) Inventors: Helmut Fischer, Lappersdorf (DE); Dieter Eissler, Nittendorf/Etterzhausen (DE); Alexander Heindl, Abensberg (DE)

Correspondence Address: SLATER & MATSIL, L.L.P., 17950 PRESTON RD, SUITE 1000, DALLAS, TX, 75252-5793, US

(21) Appl. No.: 12/663,669

(22) PCT Filed: May 7, 2008
(86) PCT No.: PCT/DE2008/000776

§ 371 Date: Dec. 8, 2009

(30) Foreign Application Priority Data
Jun. 29, 2007 (DE) 102007030314.0
Sep. 14, 2007 (DE) 102007043877.1

(51) Int. Cl. H01L 23/48; H01L 21/50

(52) U.S. Cl. 257/734; 438/107; 257/E21.499; 257/E23.01

(57) ABSTRACT

A method of producing optoelectronic components is indicated, in which a plurality of semiconductor bodies, each with a semiconductor layer sequence, are provided. In addition, a component carrier assembly with a plurality of connection pads is provided. The semiconductor bodies are positioned relative to the component carrier assembly. An electrically conductive connection is produced between the connection pads and the associated semiconductor bodies and the semiconductor bodies are attached to the component carrier assembly. The optoelectronic components are finished in that one component carrier (30) is formed from the component carrier assembly, to which the semiconductor bodies are attached, for each optoelectronic component.

This patent application is a national phase filing under section 371 of PCT/DE2008/000776, filed May 7, 2008, which claims the priority of German patent applications 10 2007 030 314.0, filed Jun. 29, 2007 and 10 2007 043 877.1 filed Sep. 14, 2007, each of which is incorporated herein by reference in its entirety.

### TECHNICAL FIELD

The present application relates to a method of producing a plurality of optoelectronic components and to an optoelectronic component.

### BACKGROUND

Optoelectronic components are generally produced in a large number of individual steps. For example, semiconductor chips provided for producing radiation are often inserted into housing bodies. This may be performed by means of the “pick-and-place method”, in which the semiconductor chips are placed individually in the housing bodies. Such production of optoelectronic components is comparatively complex and cost-intensive.

### SUMMARY

In one aspect, the invention specifies a method with which a plurality of optoelectronic components may be more simply produced, preferably by a mass production method. It is additionally intended to indicate an optoelectronic component which may be more simply produced.

According to an embodiment, in a method of producing a plurality of optoelectronic components, a plurality of semiconductor bodies each with a semiconductor layer sequence are provided. In addition, a component carrier assembly with a plurality of connection pads is provided. The semiconductor bodies are positioned relative to the component carrier assembly. An electrically conductive connection is produced in each case between the connection pads and the associated semiconductor bodies and these semiconductor bodies are attached to the component carrier assembly. The plurality of optoelectronic components are finished by forming one component carrier from the component carrier assembly for each optoelectronic component.

The component carriers are thus formed from the component carrier assembly once the associated at least one semiconductor body has been attached to a region of the component carrier assembly intended for the component carrier and connected electrically conductively to the corresponding connection pad. A complex pick-and-place method for mounting the semiconductor bodies in separate component carriers may be dispensed with. Production of the optoelectronic components is thus simplified.

In an embodiment, the semiconductor bodies are provided on an auxiliary carrier. The semiconductor bodies are thus arranged on an auxiliary carrier. This auxiliary carrier may be positioned in such a way relative to the component carrier assembly that the semiconductor bodies face the component carrier assembly. In this way, a large number of semiconductor bodies may be positioned, in particular, simultaneously, relative to the component carrier assembly. Production is thereby simplified.

In an alternative embodiment, the semiconductor bodies are arranged individually, for instance using a pick-and-place method, on the component carrier assembly. The individual semiconductor bodies may in this way be positioned mutually independently.

In a preferred embodiment, the semiconductor bodies are in each case formed on a growth substrate body for the semiconductor layer sequence of the semiconductor body. The growth substrate bodies may, in particular, after production of the electrically conductive connection between the connection pads and the semiconductor bodies, be completely removed or partially removed, for instance thinned over the entire area or in places or removed in places. The growth substrate bodies may thus serve during production of the optoelectronic components, in particular, for mechanically stabilizing of the semiconductor bodies. Additional mechanical stabilization of the semiconductor bodies may thus be dispensed with. In the finished optoelectronic component, on the other hand, the growth substrate bodies are no longer needed for this purpose. Instead, the growth substrate bodies may be completely removed during production. Thus, the growth substrate bodies may be selected independently of their optical properties.

According to a further embodiment, in a method of producing a plurality of optoelectronic components, a plurality of semiconductor bodies each with a semiconductor layer sequence are provided, the semiconductor bodies in each case being provided on a growth substrate body for the semiconductor layer sequence. In addition, a plurality of component carriers are provided, which each comprise at least one connection pad. The semiconductor bodies are positioned relative to the component carriers. An electrically conductive connection is produced between the connection pads of the component carriers and the semiconductor bodies assigned to the connection pads and these semiconductor bodies are attached to the component carriers. The plurality of optoelectronic components are finished, wherein the growth substrate bodies are removed completely or in part, for instance are thinned over the entire area or in places or removed in places, from the respective semiconductor bodies after production of the electrically conductive connection and attachment of the semiconductor bodies to the component carrier.

Removal of the growth substrate bodies thus takes place after the semiconductor bodies have already been attached to the associated component carrier. Before the semiconductor bodies are attached to the component carrier, therefore, the growth substrate bodies may serve in mechanical stabilization of the associated semiconductor bodies. In the finished optoelectronic component the growth substrate bodies are no longer or only partially present. With the growth substrate bodies completely removed, the optoelectronic properties of the optoelectronic components are independent of the growth substrate body. The growth substrate bodies for the semiconductor layer sequence of the semiconductor bodies may thus be selected independently of their optical properties. In particular, the growth substrate bodies may be configured to be opaque to the radiation produced in the semiconductor body.

In a variant of the further embodiment, the semiconductor bodies are provided on an auxiliary carrier. The semiconductor bodies are thus arranged on an auxiliary carrier. This auxiliary carrier may be positioned in such a way relative to the component carriers that the semiconductor bodies face the component carriers. In this way, a large number of semiconductor bodies may be positioned, in particular simultaneously, relative to the component carriers. Production is thereby simplified.

In an alternative variant of the further embodiment, the semiconductor bodies are arranged individually, for instance using a pick-and-place method, on the component carriers. The individual semiconductor bodies may in this way be positioned mutually independently.

In a preferred configuration of the further embodiment of the method, the component carriers are provided in a component carrier assembly. The component carriers may be formed from the component carrier assembly. Particularly preferably, the component carriers are formed after complete or partial removal of the growth substrate bodies from the component carrier assembly.

The optoelectronic components may be finished by singulation of the component carrier assembly into the component carriers. It is thus possible to dispense with complex production steps which have to be performed on individual component carriers after singulation of the component carrier assembly. Production of the optoelectronic components is thus simplified.

When the semiconductor bodies are attached to the component carriers, the auxiliary carrier and the component carrier assembly are preferably parallel or substantially parallel to one another. The semiconductor bodies may in this way be provided in planar fashion on the component carrier assembly.

The component carriers are moreover preferably formed from the component carrier assembly once the growth substrate bodies have been removed from the respective semiconductor bodies. Removal of the growth substrate bodies may in this way still be performed on the assembly.

The semiconductor bodies preferably each comprise at least one active region, which is provided for producing radiation. The radiation produced may be incoherent, partially coherent or coherent. In particular, the semiconductor bodies may be embodied as luminescent diode semiconductor bodies, for instance LED semiconductor bodies, RCLED (resonant cavity light emitting diode) or laser diode semiconductor bodies.

In a preferred configuration, a contact area is provided on at least one semiconductor body, which contact area is connected electrically conductively with the associated connection pad on the component carrier. It is also preferable for a further contact area to be provided on the semiconductor body, which contact area is connected with a further connection pad on the component carrier. The semiconductor body may thus comprise two contact areas, which are in each case connected to a connection pad. When the optoelectronic component is in operation, an electric current may be injected via the contact areas into the active region of the semiconductor body provided for producing radiation by application of an external electrical voltage between the connection pads.

In a preferred further development, the contact area and the further contact area are provided on the same side of the active region. The semiconductor body is thus electrically contactable from one side. In particular, the contact area and the further contact area may form a common plane on a side remote from the semiconductor body. In other words, the contact area boundary surfaces remote from the semiconductor body may extend within one plane. Electrical contacting of the semiconductor body is thereby more extensively simplified.

The contact areas preferably contain a metal or a metal alloy.

In a preferred configuration, the component carrier is in each case selected from the group consisting of a printed circuit board, a metal core printed circuit board, a ceramic body with connection pads and a lead frame. In particular, the component carrier may be of rigid or flexible construction.

When producing the optoelectronic components, the component carriers may, for example, emerge from the component carrier assembly by means of mechanical separation. In particular, the component carriers may be formed by means of sawing, cutting, punching or breaking out of the component carrier assembly.

Alternatively, it is also possible to use electromagnetic radiation, in particular, coherent radiation, for instance laser radiation, to form the component carriers from the component carrier assembly.

In a further preferred configuration the auxiliary carrier is provided with separate semiconductor bodies, which have been preselected particularly preferably with regard to their functionality and more specifically with regard to their optoelectronic properties, for instance brightness, radiation emission characteristic or color locus. In particular, the optoelectronic properties may be measured with regard to these properties even prior to mounting of the semiconductor bodies on the respective component carriers. In this way it can be ensured that the component carriers are in each case populated only with semiconductor bodies which match the predetermined optoelectronic properties.

Measurement of these properties may proceed even before the semiconductor bodies are placed on the auxiliary carrier. Alternatively or in addition, measurements may be performed on the auxiliary carrier. Semiconductor bodies which do not match the predetermined optoelectronic properties may then be removed from the auxiliary carrier and furthermore preferably replaced by another semiconductor body.

In a preferred further development, the semiconductor bodies are detached selectively from the auxiliary carrier once the semiconductor bodies have been attached to the component carrier. In particular, the semiconductor bodies may be detached from the auxiliary carrier by selectively exposing the auxiliary carrier to light, for instance using coherent radiation, for instance laser radiation.

The semiconductor bodies, which have been provided for attachment to the component carrier or to the component carrier assembly, each preferably have assigned to them a mounting region on the component carrier or the component carrier assembly.

Particularly preferably, those semiconductor bodies are separated from the auxiliary carrier which, on positioning of the auxiliary carrier, are arranged inside the mounting region on the component carrier or the component carrier assembly. Semiconductor bodies which, relative to the component carrier or to the component carrier assembly, are arranged outside a mounting region may remain on the auxiliary carrier and, for example, be attached in a subsequent production step to a further component carrier or component carrier assembly. In particular, all the semiconductor bodies arranged on the auxiliary carrier may be mounted on a component carrier or component carrier assembly.

Furthermore, at least one further semiconductor body may be arranged on the auxiliary carrier between two semiconductor bodies which are attached next to one another during mounting of the semiconductor bodies on the component carriers or on the component carrier assembly. The number of semiconductor bodies which are arranged over a surface area of the auxiliary carrier may thus exceed the number of mounting regions on the component carriers or on the component carrier assembly over a surface area of identical size. The packing density of the semiconductor bodies on the auxiliary carrier may thus be greater than the packing density of the mounting regions on the component carrier assembly or on the component carriers.

The semiconductor bodies may, for example, in a checkered pattern, alternately either remain on the auxiliary carrier or be mounted on a component carrier or the component carrier assembly.

The auxiliary carrier may be of rigid or mechanically flexible construction. A flexible auxiliary carrier may if necessary be arranged, on the side remote from the semiconductor bodies, on a further carrier which mechanically stabilizes the auxiliary carrier.

In a preferred further development the auxiliary carrier is embodied as a film. A film is particularly suitable whose adhesion characteristics with regard to the semiconductor bodies may be influenced, in particular, reduced, in a targeted manner. This may be achieved, for example, by means of electromagnetic radiation, in particular, coherent radiation, for instance laser radiation. In this way, the semiconductor bodies may be selectively removed from the auxiliary carrier in a simplified manner.

After attachment of the semiconductor bodies to the component carrier, the auxiliary carrier, in particular, the auxiliary carrier in the form of a film, may be removed completely from the semiconductor body.

Alternatively, a part of the auxiliary carrier, in particular, of the auxiliary carrier in the form of a film, may also remain on the semiconductor body in the finished optoelectronic component. Traces remaining on the semiconductor body merely as a result of manufacture, for instance residues of a bonding agent, are not here understood as part of the auxiliary carrier. For example, a covering for the semiconductor body or a housing body for the semiconductor body may be formed by means of the film.

In a preferred configuration, the growth substrate bodies are removed from the respective semiconductor bodies by means of coherent radiation, for instance laser radiation. Alternatively, the growth substrate bodies may be removed from the respective semiconductor bodies by means of a chemical process, for instance wet chemical or dry chemical etching, and/or by means of a mechanical process, for instance grinding, lapping or polishing.

In a preferred further development an optoelectronic property of at least one optoelectronic component is adjusted after attachment of the respective semiconductor body to the component carrier.

It is also preferable for a radiation conversion material to be provided on the respective semiconductor bodies. By means of this radiation conversion material, the spectral radiation emission characteristic of the optoelectronic component may be adjusted. Some of the radiation produced in the active region of the semiconductor body may be converted by the radiation conversion material into radiation of a different wavelength. For instance, polychromatic light, in particular light which appears white to the human eye, may be produced.

Particularly preferably, the radiation conversion material is selectively adapted to the respective semiconductor body with regard to quantity and/or composition. To this end, the semiconductor bodies may be characterized before or after attachment to the auxiliary carrier, in particular, with regard to functionality and optoelectronic properties. Alternatively or in addition, measurement of optoelectronic properties, for instance brightness and/or color locus, may be performed after attachment of the semiconductor body to the component carrier or to the component carrier assembly.

In particular, the color locus of the optoelectronic component may be conformed to a predetermined radiation emission characteristic by apportioning the radiation conversion material in a manner adapted to the respective semiconductor body.

In a preferred configuration at least one semiconductor body is provided with an optical element. This preferably takes place before the component carriers are formed from the component carrier assembly.

The optical element may be prefabricated and, for example, be attached to the component carrier or the component carrier assembly by means of a mechanical connection or an adhesive bond.

Alternatively, the optical element may be formed on the semiconductor body. In this case, the optical element may be formed by means of a molding composition, which extends around the semiconductor body at least in places and is suitably configured depending on the predetermined radiation emission characteristic. The molding composition may contain, for example, a plastic or a silicone.

The optical element may, for example, take the form of a lens or of an optical fiber.

In a further preferred configuration, the semiconductor body is textured. The texturing may be provided, in particular, to increase the coupling-out efficiency of the semiconductor body. The texturing is preferably provided on a side of the semiconductor body remote from the component carrier. For example, the semiconductor body or a layer adjoining the semiconductor body may be roughened. Alternatively or in addition, a photonic crystal may be arranged and/or formed on the semiconductor body.

The texturing may be produced, for example, mechanically, for instance by means of grinding, lapping or polishing, or chemically, for instance by means of wet chemical or dry chemical etching.

In a further preferred configuration, a filler material is introduced between the component carriers or the component carrier assembly and the associated semiconductor bodies. An interspace, which may form between the semiconductor body and the component carrier or the component carrier assembly upon attachment of the semiconductor body to the component carrier or the component carrier assembly, may thus be filled at least in places. The interspace may form between the connection pads and/or between the contact areas, in particular, in the lateral direction, i.e., along a main direction of extension of the component carrier or of the component carrier assembly. The filler material may mechanically stabilize the semiconductor bodies, in particular, upon detachment of the respective growth substrate body.

The filler material is preferably such that capillary effects favor introduction of the filler material into interspaces. To this end, the filler material preferably exhibits low viscosity.

In addition, the filler material is conveniently electrically insulating. In this way, electrical short circuits between two adjacent connection pads may be prevented.

The filler material preferably contains an organic material, for instance a resin, in particular, a reactive resin. For example the filler material may contain an epoxy resin. Furthermore, the filler material may take the form of an adhesive.

Particularly preferably, the filler material is introduced prior to detachment of the respective growth substrate body. In this way, the filler material may mechanically stabilize the semiconductor body, in particular, on detachment of the growth substrate body.

It is also preferable for the filler material to be introduced into the interspace in a flowable state and then cured. Curing may, in particular, be heat-induced or be induced by electromagnetic radiation, in particular, ultraviolet radiation.

In a preferred configuration, the optoelectronic components are produced in an apparatus in which the described production steps are performed. The production steps may here be performed in a completely or partly automated manner, in particular, in succession. Production of the optoelectronic components is thereby simplified.

According to an embodiment, an optoelectronic component comprises a component carrier with at least two connection pads and a semiconductor body with a semiconductor layer sequence. The semiconductor layer sequence of the semiconductor body preferably comprises an active region provided for producing radiation. At least two contact areas are formed on the semiconductor body and are connected electrically conductively in each case to a connection pad. An interspace between the semiconductor body and the component carrier is filled at least partially with a filler material.

The filler material serves, in particular, for mechanical stabilization of the semiconductor body. The semiconductor body may thus be mechanically stabilized by means of the filler material both during production of the optoelectronic component and when the optoelectronic component is in operation. In particular, in this way production of the optoelectronic component is simplified, for instance detachment of a growth substrate body for the semiconductor body.

In a preferred configuration the interspace is bounded laterally, i.e., along a main direction of extension of the component carrier, by the connection pads and/or by the contact areas. In particular, the interspace may extend laterally between the connection pads and/or between the contact areas. The interspace may be filled completely or partially with the filler material.

The contact areas are preferably provided on the same side of the active region. Production of an electrically conductive connection to the connection pads of the component carrier is thus simplified.

In a preferred configuration, the semiconductor body, in particular, the active region, contains a III-V semiconductor material. With III-V semiconductor materials high internal quantum efficiencies can be achieved during radiation generation.

The method described further above is particularly suitable for production of the optoelectronic component. Features listed in connection with the above-described method may therefore also be used for the optoelectronic component and vice versa.

### BRIEF DESCRIPTION OF THE DRAWINGS

Further features, advantageous configurations and convenient aspects are revealed by the following description of the exemplary embodiments in conjunction with the Figures, in which:

FIGS. 1A to 1H are schematic sectional views of a first exemplary embodiment of a method of producing optoelectronic components, showing intermediate steps,

FIGS. 2A to 2G are schematic sectional views of a second exemplary embodiment of a method of producing optoelectronic components, showing intermediate steps,

FIGS. 3A to 3G are schematic sectional views of a third exemplary embodiment of a method of producing optoelectronic components, showing intermediate steps,

FIG. 4 is a schematic sectional view of an exemplary embodiment of a semiconductor body, and

FIG. 5 is a schematic sectional view of an exemplary embodiment of an optoelectronic component.

Identical, similar and identically acting elements are provided with identical reference numerals in the Figures.

The figures are in each case schematic representations and are therefore not necessarily true to scale. Rather, comparatively small elements and, in particular, layer thicknesses may be illustrated on an exaggeratedly large scale for clarification.

### DETAILED DESCRIPTION OF ILLUSTRATIVE EMBODIMENTS

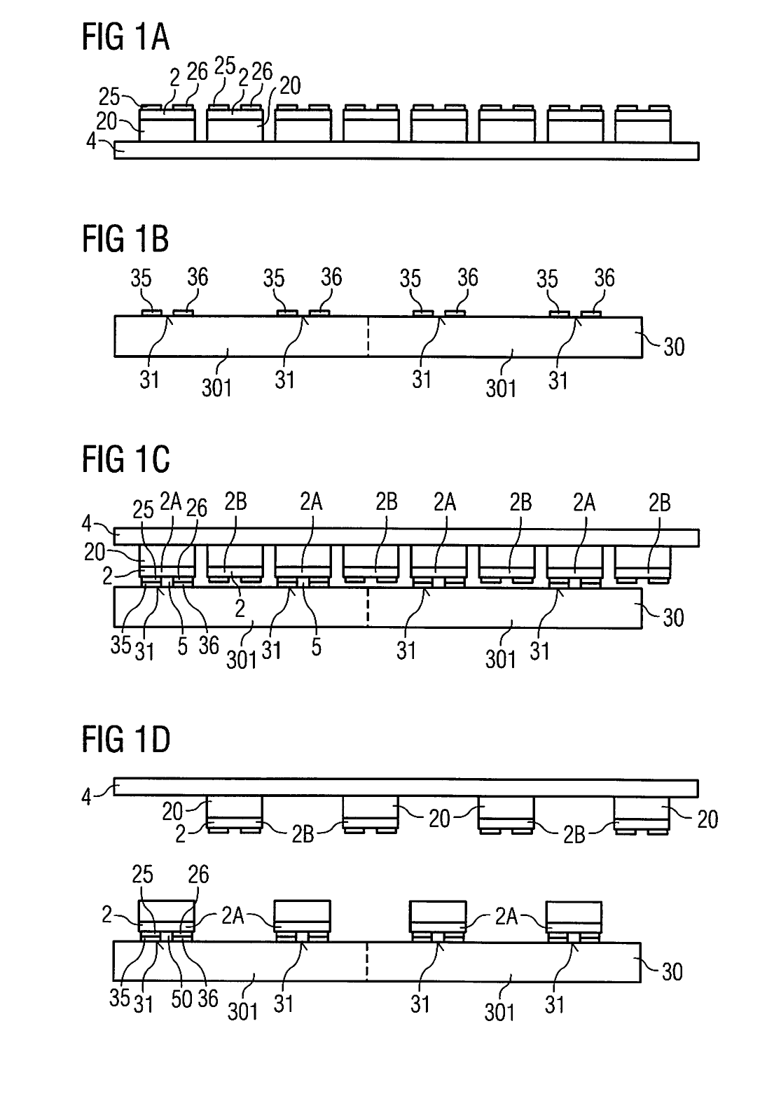

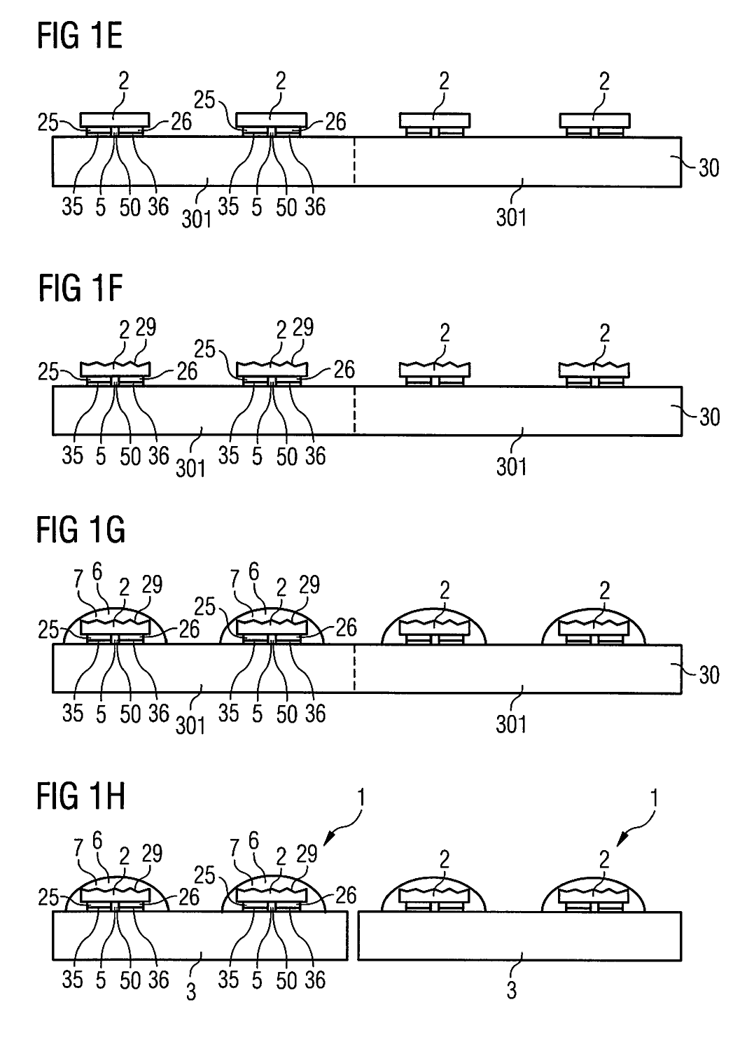

FIGS. 1A to 1H are schematic sectional views of a first exemplary embodiment of a method of producing optoelectronic components, showing intermediate steps.

As is shown in FIG. 1A, a plurality of semiconductor bodies 2, each with a semiconductor layer sequence, are provided on an auxiliary carrier 4. The semiconductor layer sequence forms the semiconductor body 2. The semiconductor bodies 2 are each arranged on a growth substrate body 20. The semiconductor layer sequence of the semiconductor bodies is preferably produced using an epitaxial method, for instance MOVPE or MBE. The semiconductor bodies are each arranged on the side of the growth substrate bodies 20 remote from the auxiliary carrier 4.

A contact area 25 and a further contact area 26 are in each case provided on the sides of the semiconductor bodies 2 remote from the respective growth substrate bodies 20. The contact area 25 and the further contact area 26 are thus arranged on the same side of the semiconductor body.

The contact areas 25, 26 are conveniently of electrically conductive construction. Preferably, the contact areas contain a metal, for instance Au, Sn, Ni, Ti, Al or Pt, or a metal alloy comprising at least one of the stated metals, for instance AuGe or AuSn. The contact areas may also be of multilayer construction.

The semiconductor bodies 2 with the growth substrate bodies 20 and the contact areas 25, 26 are illustrated in a greatly simplified manner in FIG. 1A for greater clarity. For example, the semiconductor bodies may each comprise an active region for producing radiation. This is not shown explicitly in FIG. 1A. The semiconductor body may, for example, be provided as an LED semiconductor body, as an RCLED semiconductor body or as a laser diode semiconductor body. Accordingly, the radiation emitted in operation may be incoherent, partially coherent or coherent.

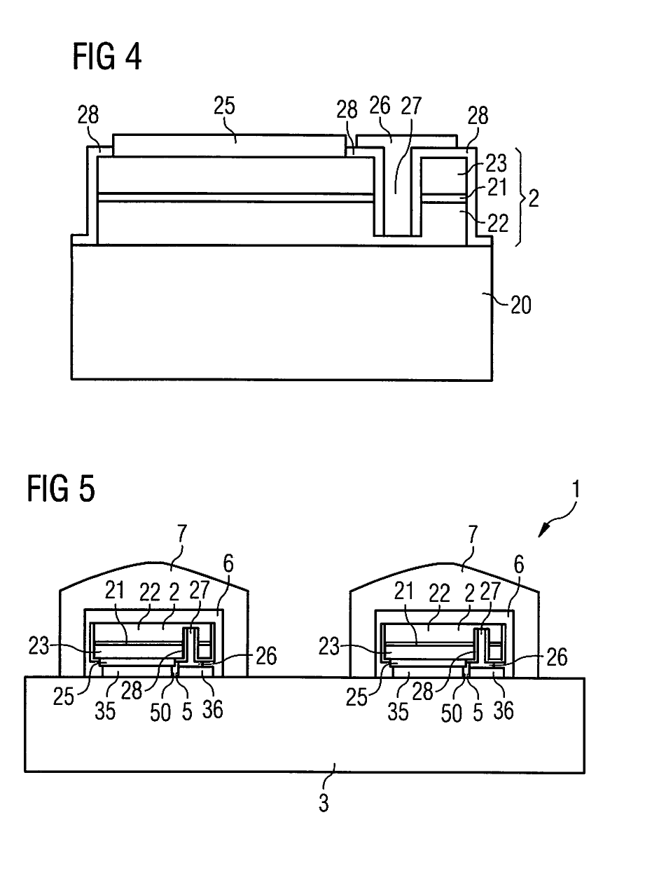

In particular, the semiconductor bodies 2 and/or the growth substrates 20 may be constructed as described in connection with FIG. 4 or comprise at least one of the features described in relation to FIG. 4.

In an embodiment, the auxiliary carrier 4 is embodied as a rigid carrier.

In an alternative configuration embodiment, the auxiliary carrier 4 is embodied as a film. The auxiliary carrier may thus be mechanically flexible. Optionally, the film may be mechanically stabilized by a further carrier, in particular, on the side remote from the semiconductor bodies 2.

FIG. 1B shows a component carrier assembly 30, in which mounting regions 31 are provided. The mounting regions are each provided for the attachment of semiconductor bodies. In the mounting regions in each case a connection pad 35 and a further connection pad 36 are formed on the component carrier assembly 30.

In the exemplary embodiment shown, a component carrier assembly 30 is shown merely by way of example, from which two component carriers result upon production of the optoelectronic components, one component carrier being formed in each case from the component carrier assembly regions 301. Two semiconductor bodies are in each case arranged on each component carrier assembly region 301. It goes without saying that a number of semiconductor bodies 2 other than two, for example, one semiconductor body or three or more semiconductor bodies, may also be arranged on one component carrier assembly region 301. In addition, more than two component carriers may also result from one component carrier assembly.

The component carrier 3 may be of rigid or flexible construction. For example, a printed circuit board (PCB) is suitable. A metal core printed circuit board (MCPCB) may also be used. Such a printed circuit board is distinguished in particular by high thermal conductivity. Heat generated when the optoelectronic components in the semiconductor body are in operation may in this way be particularly efficiently dissipated.

Alternatively, the component carriers 3 may also contain a ceramic and, for example, take the form of ceramic bodies, on which in each case electrically conductive connection pads may be provided. In addition, the component carriers 3 may also take the form of preferably metallic lead frames. In this case the component carrier assembly 30 may, for example, comprise a metal sheet, from which the lead frames are formed.

The auxiliary carrier 4 is positioned in such a way relative to the component carrier assembly 30 that the semiconductor bodies 2 face the component carrier assembly 30 (FIG. 1C). The auxiliary carrier 4 may then be arranged in planar fashion over the component carrier assembly 30.

Positioning proceeds conveniently in that, in plan view, the connection pads 35, 36 overlap with the associated contact areas 25, 26 of the associated semiconductor body 2A and are preferably in mechanical contact therewith. Between the connection pad 35 and the contact area 25 and between the further connection pad 36 and the further contact area 26 an electrically conductive connection is produced. This may be achieved, for example, by soldering. Alternatively or in addition, an electrically conductive adhesive may also be used. The semiconductor bodies 2A may in this way be mechanically stably connected with the component carrier assembly 30.

The semiconductor bodies 2 may thus also be attached mechanically stably to the component carrier assembly region 301 upon production of the electrically conductive connection with the connection pads 35, 36. Alternatively or in addition, the semiconductor bodies 2 may also be attached to the component carrier assembly separately from the electrically conductive connection, for instance by means of adhesive bonding.

A further semiconductor body 2B is in each case arranged by way of example on the auxiliary carrier 4 between the semiconductor bodies 2A. These semiconductor bodies 2B are arranged relative to the component carrier assembly in such a way that they are located outside the mounting regions 31. These semiconductor bodies 2B are not connected mechanically to the component carrier assembly 30 in the above-described method step and remain on the auxiliary carrier 4. For example, the semiconductor bodies 2A provided for mounting and the semiconductor bodies 2B remaining on the auxiliary carrier form a checkered pattern on the auxiliary carrier. On the other hand, a different pattern may also be convenient. Conveniently, the pattern is conformed to the arrangement of the mounting regions 31 on the component carrier assembly 30. In particular, the pattern may copy the arrangement of the mounting regions 31.

More semiconductor bodies 2 may thus be provided over a surface area of the auxiliary carrier 4 than mounting regions made available by the component carrier assembly 30 over a surface area of the same size. Accordingly, the semiconductor bodies 2 on the auxiliary carrier 4 may be arranged with a higher packing density than the mounting regions on the component carrier assembly.

To populate the component carrier assembly regions 301 of the component carrier assembly 30, in each case those semiconductor bodies 2A are conveniently connected mechanically stably with the component carrier assembly 30 which lie inside a mounting region 31 on the component carrier assembly, wherein, in particular, the contact areas 25, 26 thereof may overlap with connection pads on the component carrier assembly 30. In other words, those semiconductor bodies may be selected from the semiconductor bodies 2 which are offered on the auxiliary carrier 4 at a greater packing density for mounting on the component carrier assembly 30 which are suitably positioned relative to the mounting regions 31.

The semiconductor bodies 2A, with the associated growth substrate bodies 20, are then removed selectively from the auxiliary carrier 4 (FIG. 1D). The semiconductor bodies 2B, on the other hand, remain mechanically connected to the auxiliary carrier 4 and may be removed from the component carrier assembly 30 with the auxiliary carrier 4.

Selective detachment of the semiconductor bodies 2A from the auxiliary carrier 4 may be effected, for example, by local modification of the adhesive characteristics of the auxiliary carrier 4. In particular, an auxiliary carrier is suitable whose adhesive characteristics may be locally reduced by means of exposure to light. Electromagnetic radiation, for example, in particular, coherent radiation, for instance laser radiation, is suitable for this purpose which is directed in a targeted manner onto the auxiliary carrier in the area of the semiconductor body 2A to be detached. The auxiliary carrier 4 may, for example, be a film whose properties of adhesion to the semiconductor body or the associated growth substrate body may be reduced by means of exposure to light.

The connection pad 35 and the further connection pad 36 are conveniently spaced from one another. When attaching the semiconductor bodies 2 to the component carrier, an interspace 5 may in each case arise between the semiconductor bodies and the component carrier assembly 30 (FIG. 1C). These interspaces 5 may be filled in at least in places by means of a filler material 50. The filler material is preferably such that capillary effects favor penetration of the filler material 50 into the interspaces 5.

The filler material 50 is conveniently introduced into the interspace 5 in a flowable state. Preferably, the filler material exhibits low viscosity. Penetration into small interspaces is thereby made easier. Then the filler material may if necessary be cured. Curing may, for example, be heat-induced or be induced by electromagnetic radiation, in particular, ultraviolet radiation. In addition, the filler material 50 is preferably electrically insulating.

The filler material 50 preferably contains an organic material, for instance a resin, in particular, a reactive resin. For example the filler material may contain an epoxy resin. Furthermore, the filler material may take the form of an adhesive.

As shown in FIG. 1E, the growth substrate bodies 20 may be removed from the respective semiconductor bodies 2. The filler material 50 serves, in particular, for mechanical stabilization of the semiconductor body 2.

Removal of the growth substrate body 20 may proceed completely or partially. Preferably, a laser detachment method is used. Alternatively, the growth substrate bodies may also be thinned or completely removed by means of a chemical process, for instance wet chemical or dry chemical etching, and/or a mechanical process, for instance grinding, lapping or polishing. The material of the growth substrate bodies 20 may, for example, be sucked away after it has been detached from the semiconductor bodies.

During production of the optoelectronic components, the growth substrate bodies 20 serve for mechanical stabilization of the respective semiconductor body 2. More extensive stabilization by means of an additional carrier is unnecessary for this purpose. In the described method the growth substrate bodies 20 are removed once the semiconductor bodies 2 have been attached to the component carrier assembly 30, from which component carriers are produced.

In the finished optoelectronic component 1, on the other hand, the growth substrate bodies no longer have to be present (FIG. 1H). The growth substrate for the semiconductor layer sequence of the semiconductor bodies 2 may thus be selected largely independently of optical properties.

Furthermore, in the finished optoelectronic component 1 the semiconductor bodies 2 may be mechanically stabilized by the component carrier 3. It is possible to dispense with an additional carrier, for instance on the side of the semiconductor body remote from the component carrier. In this way, the structural height of the optoelectronic component 1 may be reduced.

As FIG. 1F shows, the semiconductor bodies 2 is provided with a structure 29, improving the coupling-out efficiency from the semiconductor bodies. The proportion of radiation which is produced in the respective active regions when the optoelectronic components are in operation and is emitted by the semiconductor bodies may thus be increased.

Structuring of the semiconductor bodies 2 or of a layer arranged on the semiconductor bodies may be effected, for example, mechanically, for instance by means of grinding, lapping, polishing, or chemically, for instance by means of wet chemical or dry chemical etching. The structuring may be irregular or regular. Multiple reflection of radiation at boundary surfaces of the semiconductor body as a result of total reflection may be reduced by means of the structuring. Furthermore, the structuring may be formed in accordance with a photonic crystal.

In order to influence the spectral characteristic of the optoelectronic component to be produced, a radiation conversion material, for instance a luminescence converter or a phosphorus, may be provided on the semiconductor body 2. The radiation conversion material may be configured, for example, as a covering 6 (FIG. 1G) for the semiconductor body 2. Radiation produced in the semiconductor body 2 may be at least partially converted by the radiation conversion material into radiation of a different wavelength. In this way, polychromatic light, preferably light which appears white to the human eye, may be emitted by the optoelectronic component.

On the other hand, the radiation conversion material may also be provided in a separate layer different from the covering 6, which may be applied to the semiconductor bodies on the side remote from the component carrier assembly 30. The covering may, for example, contain a resin, in particular, a reactive resin or a silicone.

In particular, the spectral characteristic of the radiation emitted by semiconductor bodies may be measured prior to application of the radiation conversion material and the quantity and/or composition of the radiation conversion material may be adjusted on the basis of the measurement results. In this way, for example the color locus of the optoelectronic component in the CIE diagram may be adjusted particularly precisely.

In addition, the quantity and/or composition of the radiation conversion material may be selectively adapted to the respective semiconductor body. The quantity and/or composition may thus be adjusted largely independently from semiconductor body to semiconductor body.

Application of the radiation conversion material may take place, for example, individually for each semiconductor body by means of a microdispenser.

Accordingly, it is also possible if necessary to adjust the brightness of the optoelectronic components 1, in particular, in accordance with a previously performed measurement of the radiant power emitted by the respective semiconductor body, and thus adapt it to a predetermined value. To this end, a layer may, for example, be applied to the semiconductor body which absorbs some of the radiation emitted by the semiconductor body in a targeted manner.

The covering 6 may further be shaped as an optical element 7. In this case the optical element is thus formed on the semiconductor body 2. On the other hand, the optical element may also be prefabricated and attached to the component. The optical element may, in particular, take the form of a lens or of an optical fiber. Conveniently, the optical element is made from a material which is transparent or at least translucent with regard to radiation produced in the semiconductor bodies. For example, the optical element 7 may be based on plastic, a silicone or glass or consist of such a material.

The component carriers 3 are formed from the component carrier assembly 30. This may take place, for example, by means of mechanical separation, for instance sawing, cutting, splitting, punching or breaking, or by means of coherent radiation, for instance laser radiation. Two finished optoelectronic components 1 are shown in FIG. 1H.

In the above-described method a plurality of production steps may thus be performed before the component carriers 3 are formed from the component carrier assembly 30. Production of the optoelectronic components 1 is thereby simplified. In particular, semiconductor bodies 2 with in each case one growth substrate body 20 may be mounted on the component carrier assembly 30. The growth substrate bodies 20 may then be removed, such that the optoelectronic components 1 may be free of the growth substrate bodies.

Unlike the above-described method, the semiconductor bodies 2 may also be positioned individually on the component carrier assembly and then attached, instead of the method steps described in connection with FIGS. 1C and 1D. Positioning may be effected, for example, by a pick-and-place method. The other method steps, in particular the removal of the growth substrate bodies described in connection with FIG. 1E, may be performed as described above. In this embodiment, the respective growth substrate bodies 20 may serve for mechanical stabilization of the semiconductor bodies during mounting of the semiconductor bodies and then again be removed.

The above-described method steps are preferably performed in an apparatus for a large number of optoelectronic components. In particular, performance of the method steps may be fully automated or at least partly automated. Production of the optoelectronic components is thus further simplified.

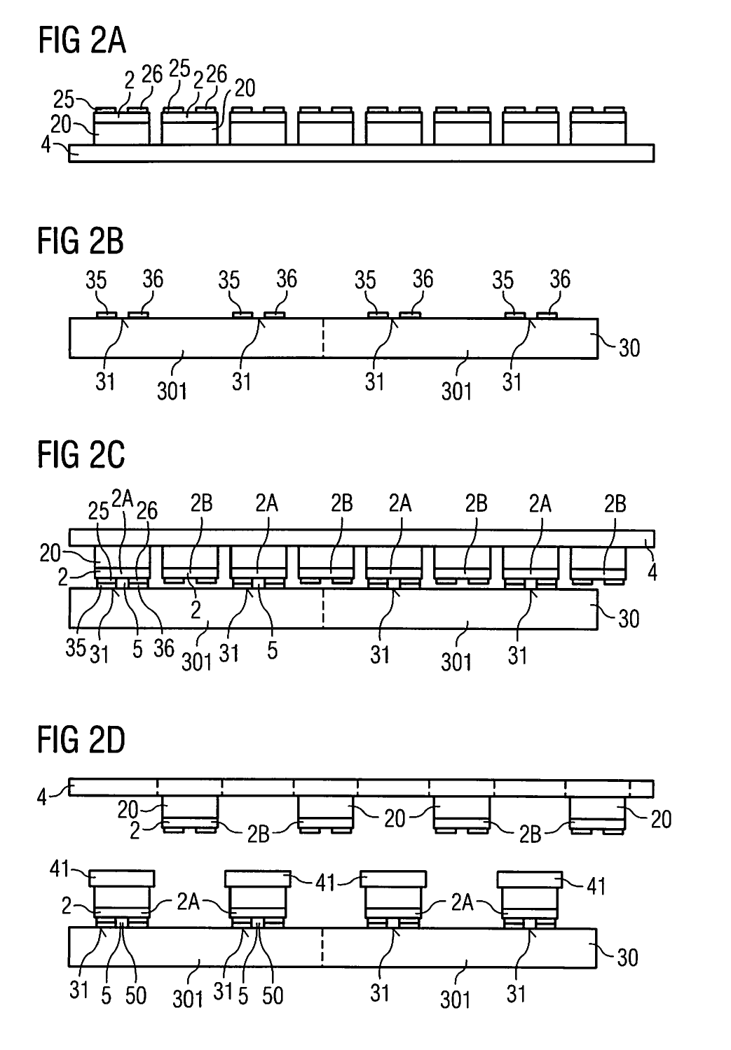

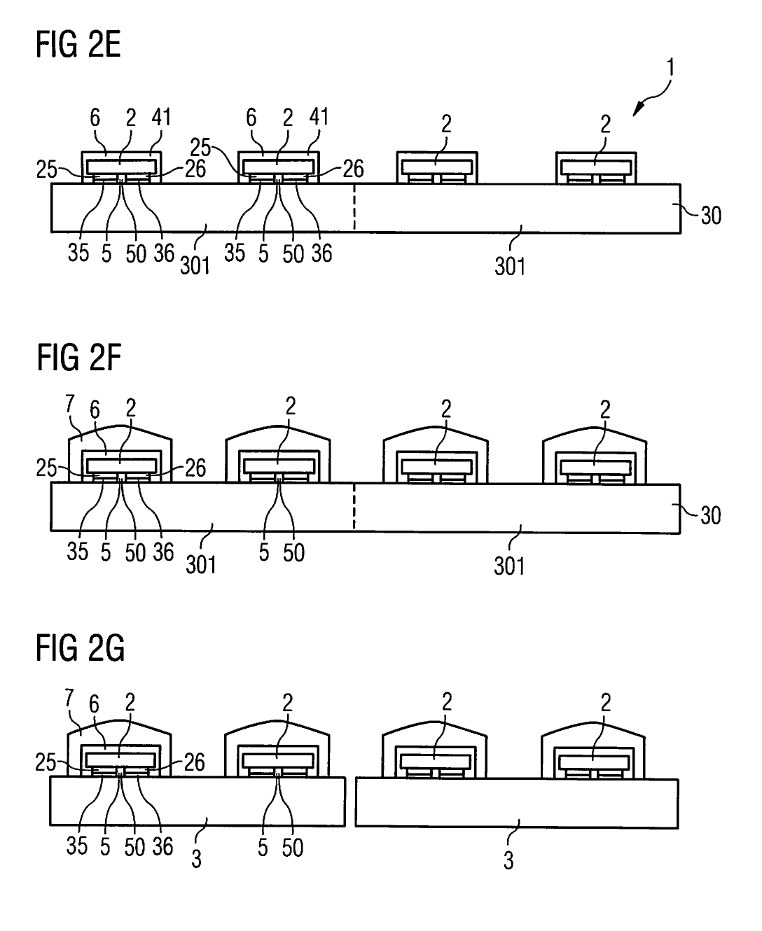

A second exemplary embodiment of a method of producing a plurality of semiconductor chips is illustrated schematically in sectional view in FIGS. 2A to 2G by way of intermediate steps. The second exemplary embodiment corresponds substantially to the first exemplary embodiment described in connection with FIGS. 1A to 1H. Unlike in the first exemplary embodiment, a part 41 of the auxiliary carrier 4 remains on the semiconductor bodies 2A, which are attached to the component carrier assembly 30. This is shown in FIG. 2D. By means of these parts of the auxiliary carrier 4, it is possible, as shown in FIG. 2E, to form a covering 6 for the semiconductor bodies 2.

By means of the covering, the semiconductor bodies 2 may be encapsulated and thereby protected from external influences. Alternatively or in addition, by means of these parts of the auxiliary carrier in each case a housing body may also be formed for the semiconductor bodies 2. For example, the auxiliary carrier 4 may be formed by means of a film, which may be molded onto the semiconductor bodies 2. This molding-on may be heat-induced, for example. For example, the semiconductor bodies may be heated together with the component carrier assembly 30 to a temperature above the melting point of the film. Alternatively, the film may also be heated locally, for example, by means of coherent radiation, for instance laser radiation.

Furthermore, unlike in the first exemplary embodiment, a prefabricated optical element 7 is attached to the component carrier assembly 30. The optical element takes the form of a plane-convex lens, for example. On the other hand, depending on the radiation emission characteristic to be achieved, another form may also be advantageous for the optical element. The optical element 7 may, for example, be attached to the component carrier 3 by adhesive bonding.

As described in connection with FIGS. 1A to 1H, a radiation conversion material (not explicitly illustrated) may be applied to the semiconductor bodies, in particular, to the covering 6.

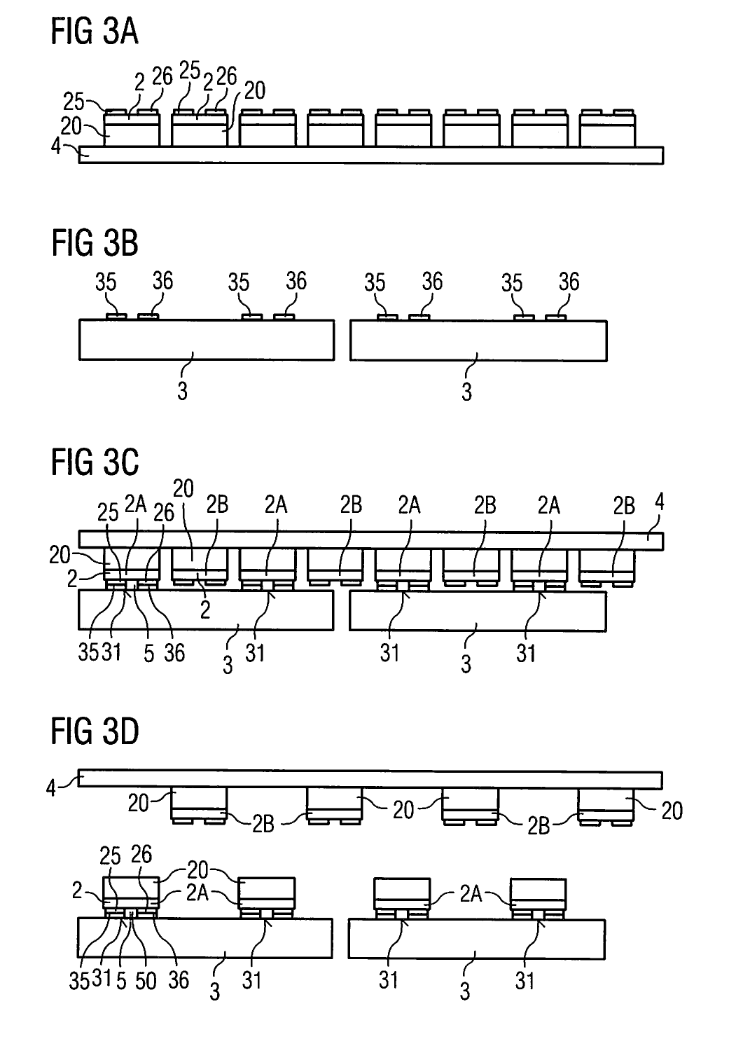

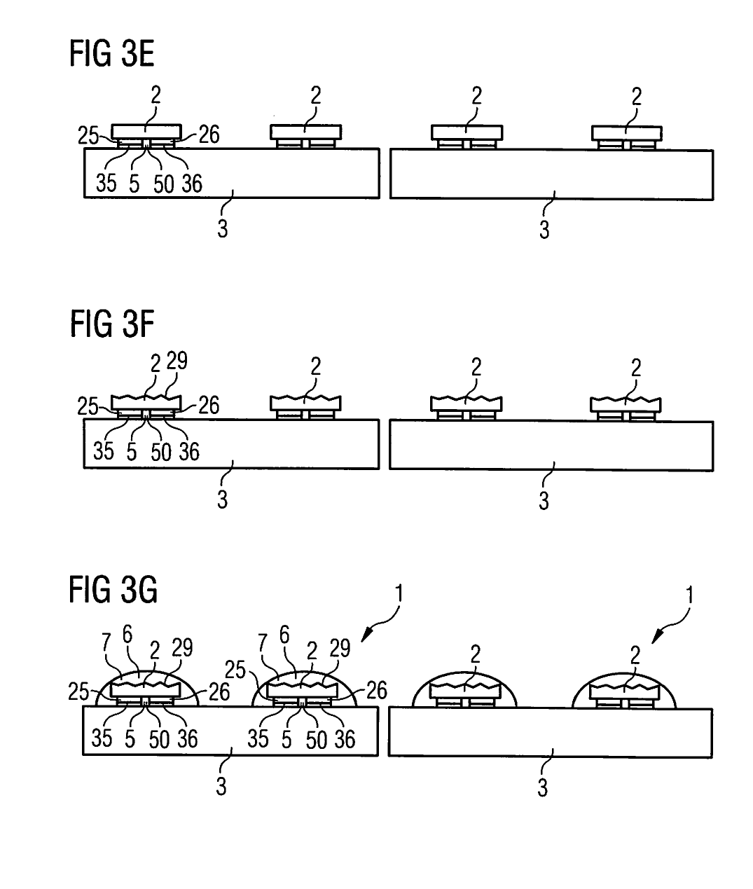

A third exemplary embodiment of a method of producing a plurality of semiconductor chips is illustrated schematically in sectional view in FIGS. 3A to 3G by way of intermediate steps. The third exemplary embodiment corresponds substantially to the first exemplary embodiment described in connection with FIGS. 1A to 1H.

Unlike in the first exemplary embodiment, as shown in FIG. 3B the component carriers 3 are provided in already prefabricated form. To this end, the component carriers may be arranged on a mounting carrier (not explicitly illustrated). The component carriers 3 are thus not provided in a component carrier assembly. The component carriers 3 each comprise by way of example two mounting regions 31 corresponding to the component carrier assembly regions 301. In the mounting regions in each case one connection pad 35 and one further connection pad 36 are formed on the component carriers 3. The component carriers 3 may in each case also comprise a different number of mounting regions, for instance one mounting region or more than two mounting regions.

The further production steps, which are shown in FIGS. 3A and 3C to 3G, may be performed as described in connection with FIGS. 1A and 1C to 1G. The component carriers 3 here correspond substantially to the component carrier assembly regions 301 of the first exemplary embodiment. In particular, the semiconductor bodies 2 associated with the mounting regions 31 are attached to the respective component carriers 3 (FIG. 3D).

In accordance with the first exemplary embodiment described in connection with FIGS. 1A to 1H, the interspaces 5, which may form between the semiconductor bodies 2 and the component carriers 3 on attachment of the semiconductor bodies to the component carriers, may be filled.

Unlike in the third exemplary embodiment shown, the features mentioned in connection with the second exemplary embodiment illustrated in FIGS. 2A to 2G may be used. In particular, the optical elements 7 may be prefabricated. Furthermore, in each case a part of the auxiliary carrier 4 may remain on the semiconductor bodies 2.

In contrast to the first exemplary embodiment, formation of the component carriers from a component carrier assembly illustrated in FIG. 1H is not necessary in a method according to the third exemplary embodiment.

Unlike the method described according to the third exemplary embodiment, the semiconductor bodies 2 may also be positioned individually on the component carriers and then attached, instead of the method steps described in connection with FIGS. 3C and 3D. Positioning may be effected, for example, by a pick-and-place method. The other method steps, in particular, the removal of the growth substrate bodies described in connection with FIG. 3E, may be performed as described above. In this embodiment, the respective growth substrate bodies 20 may serve for mechanical stabilization of the semiconductor bodies during mounting of the semiconductor bodies and then again be removed.

FIG. 4 shows a schematic sectional view of an exemplary embodiment of a semiconductor body 2 which is particularly suitable for the exemplary embodiments of the method described with reference to FIGS. 1A to 1H, 2A to 2G or 3A to 3G.

The semiconductor body 2 takes the form, by way of example, of a luminescent diode semiconductor body, which is provided for producing incoherent radiation. A semiconductor layer sequence, which comprises an active region 21, an n-conducting semiconductor layer 22 and a p-conducting semiconductor layer 23, forms the semiconductor body 2. The semiconductor layer sequence of the semiconductor body 2 is arranged on a growth substrate body 20. The growth substrate bodies 20 preferably result from singulation from a growth substrate, for instance a wafer. The semiconductor layer sequence, from which the semiconductor bodies 2 are formed, may be produced, preferably epitaxially, for instance by means of MOVPE or MBE, on the growth substrate.

The semiconductor body 2, in particular, the active region 21, preferably contains a III-V semiconductor material. III-V-semiconductor materials are particularly suitable for producing radiation in the ultraviolet (InₓGa_{y}Al_{1-x-y}N) through the visible (InₓGa_{y}Al_{1-x-y}N, in particular, for blue to green radiation, or InₓGa_{y}Al_{1-x-y}P, in particular, for yellow to red radiation) to the infrared (InₓGa_{y}Al_{1-x-y}As) range of the spectrum. Here in each case 0≦x≦1, 0≦y≦1 and x+y≦1 applies, in particular, with x≠1, y≠1, x≠0 and/or y≠0. With III-V semiconductor materials, in particular, from the stated material systems, it is additionally possible advantageously to achieve high internal quantum efficiencies during the production of radiation.

The growth substrate may, depending on the material to be deposited for the semiconductor body, for example, be a semiconductor substrate, for instance a substrate which contains GaAs, Si, SiC, GaN, InP or GaP or consists of such a material. A sapphire substrate may also be used.

The n-conducting semiconductor layer 22 is arranged between the active region 21 and the growth substrate body 20. The arrangement of the n-conducting semiconductor layer 22 and the p-conducting semiconductor layer 23 relative to the active region 21 may however also be switched, such that the p-conducting semiconductor layer 23 may be arranged between the active region 21 and the growth substrate body 20.

A contact area 25 and a further contact area 26 are provided on the side of the active region 21 remote from the growth substrate body 20. The contact area 25 and the further contact area 26 are thus arranged on the same side of the active region 21. External electrical contacting of the semiconductor body 2 may thus proceed from one side of the semiconductor body, in particular, from one side of the active region 21.

The contact areas 25, 26 are conveniently of electrically conductive construction. Preferably, the contact areas contain a metal, for instance Au, Sn, Ni, Ti, Al or Pt, or a metal alloy with at least one of the stated metals, for instance AuSn or AuGe. The contact areas may be produced, for example, by means of sputtering or vapor deposition onto the semiconductor body.

In addition, the semiconductor body 2 comprises at least one recess 27, which extends from the side of the semiconductor body 2 remote from the growth substrate body 20 right through the active region 21.

In the recess 27 the semiconductor body 2 is provided with an insulation layer 28 on the side faces of the recess 27. Moreover, the insulation layer 28 is provided between the further contact area 26 and the semiconductor body 2. The insulation layer 28 may, for example, contain an oxide, for instance silicon oxide, a nitride, for instance silicon nitride or an oxynitride, for instance silicon oxynitride.

By way of the recess 27 an electrically conductive connection between the further contact area 26 and the n-conducting semiconductor layer 22 is produced on the insulation layer 28. By applying an external electrical voltage between the contact area 25 and the further contact area 26, a current may thus flow through the active region 21 and there lead to the generation of electromagnetic radiation by recombining electron hole pairs.

On the side remote from the semiconductor body 2 the contact area 25 and the further contact area 26 preferably form a level surface. In this way, the semiconductor body 2 may be attached in a simplified manner to a component carrier.

Unlike in the exemplary embodiment illustrated, the semiconductor body 2 may also comprise two or more recesses for contacting the n-conducting semiconductor layer 22. Laterally uniform injection of charge carriers into the active region 21 may thereby be simplified.

FIG. 5 is a schematic sectional view of an exemplary embodiment of an optoelectronic component.

The optoelectronic component 1 comprises a component carrier 3. Two semiconductor bodies 2 are attached to the component carrier. The semiconductor bodies 2, on which in each case a contact area 25 and a further contact area 26 are arranged, are in each case constructed as described in connection with FIG. 4. In particular, a semiconductor layer sequence comprising an active region 21 provided for producing radiation forms the semiconductor body 2. The respective growth substrate bodies 20, on which the semiconductor body is formed as described in connection with FIG. 4, are removed completely from the semiconductor bodies in the finished optoelectronic component shown in FIG. 5. On the other hand, the growth substrate body may also be removed only in places or thinned.

The contact area 25 and the further contact area 26 are in each case connected electrically conductively to a connection pad 35 and a further connection pad 36 of the component carrier. An interspace 5 is formed between the semiconductor body 2 and the component carrier 3. The interspace 5 is defined laterally in places by the connection pads 35, 36 and/or the contact areas 25, 26.

The interspace 5 has been filled with a filler material 50. The filler material serves, in particular, for mechanical stabilization of the semiconductor body 2. The semiconductor body 2 may in this way withstand relatively heavy mechanical loads, in particular, during production of the optoelectronic component 1. Production of the optoelectronic component 1 is thereby simplified.

Unlike in the exemplary embodiment shown, the interspace 5 may also be filled only partially with the filler material 50, wherein the filler material conveniently provides sufficient mechanical stabilization for the semiconductor body 2.

The semiconductor bodies 2 are surrounded by a covering 6, which preferably encapsulates the semiconductor bodies 2. By means of the covering 6, the semiconductor bodies may in each case be protected from external influences such as moisture.

As described in connection with FIGS. 1A to 1H, a radiation conversion material may be embedded in the covering 6. Alternatively or in addition, the radiation conversion material may also be provided in a layer separate from the covering 6.

Furthermore, at least one of the semiconductor bodies may be structured as described in connection with FIG. 1F.

The further elements of the optoelectronic component 1, in particular of the component carrier 3, the connection pads 35, 36 and the optical element 7, may be constructed as described in connection with FIGS. 1A to 1H, 2A to 2G and 3A to 3G.

The invention is not restricted by the description given with reference to the exemplary embodiments. Rather, the invention encompasses any novel feature and any combination of features, including, in particular, any combination of features in the claims, even if this feature or this combination is not itself explicitly indicated in the claims or the exemplary embodiments.

1. A method of producing a plurality of optoelectronic components, the method comprising:
a) providing a plurality of semiconductor bodies each semiconductor body having a semiconductor layer sequence;
b) providing a component carrier assembly with a plurality of connection pads;
c) positioning the semiconductor bodies relative to the component carrier assembly;
d) producing an electrically conductive connection between the connection pads of the component carrier assembly and the semiconductor bodies and fixing the semiconductor bodies to the component carrier assembly; and
e) finishing the plurality of optoelectronic components, one component carrier being formed from the component carrier assembly for each optoelectronic component.

2. The method according to claim 1, wherein
in step a) the semiconductor bodies are arranged on an auxiliary carrier and in step c) the auxiliary carrier is positioned in such a way relative to the component carrier assembly that the semiconductor bodies face the component carrier assembly; and
in step a) at least one further semiconductor body is arranged on the auxiliary carrier between two semiconductor bodies which in step d) are attached next to one another on the component carrier assembly.

3. The method according to claim 1, wherein the semiconductor bodies are in each case formed on a growth substrate body for the semiconductor layer sequence of the semiconductor body, and the growth substrate bodies are removed completely or partially after step d).

4. The method according to claim 1, wherein in step b) a plurality of mounting regions are formed on the component carrier assembly, the mounting regions being provided for an attachment of a semiconductor body, and wherein the semiconductor bodies which, in step c), are positioned inside a mounting region are separated from an auxiliary carrier and the semiconductor bodies which, in step c), are arranged outside the mounting regions remain on the auxiliary carrier.

5. A method of producing a plurality of optoelectronic components, the method comprising:
a) providing a plurality of semiconductor bodies, each semiconductor body having a semiconductor layer sequence, each semiconductor body being formed on a growth substrate body for the semiconductor layer sequence of the semiconductor body;
b) providing a plurality of component carriers, each component carrier comprising at least one connection pad;
c) positioning the semiconductor bodies relative to the component carriers;
d) producing an electrically conductive connection between the connection pads of the component carriers and the semiconductor bodies and attaching these semiconductor bodies to the component carrier; and
e) finishing the plurality of optoelectronic components, the growth substrate bodies being removed completely or partially from the respective semiconductor bodies during the finishing.

6. The method according to claim 5, wherein in step b) the component carriers are provided in a component carrier assembly.

7. The method according to claim 5, wherein in step c) the semiconductor bodies are arranged individually on the component carrier assembly.

8. The method according to claim 5, wherein
in step a) the semiconductor bodies are arranged on an auxiliary carrier and in step c) the auxiliary carrier is positioned in such a way relative to the component carriers that the semiconductor bodies face the component carriers, and
in step a) at least one further semiconductor body is arranged on the auxiliary carrier between two semiconductor bodies which in step d) are attached next to one another on the component carriers.

9. The method according to claim 8, wherein in step a) the auxiliary carrier is provided with separate semiconductor bodies, which have been preselected with regard to their optoelectronic properties.

10. The method according to claim 8, wherein the semiconductor bodies are selectively detached from the auxiliary carrier after step d).

11. The method according to claim 8, wherein the auxiliary carrier is embodied as a film.

12. The method according to claim 11, wherein, in the finished optoelectronic component, a part of the film remains on the semiconductor body.

13. The method according to claim 5,
wherein in step b) at least one mounting region is formed on each component carrier, the mounting region being provided for attaching a semiconductor body, and
wherein semiconductor bodies which in step c) are arranged in each case inside a mounting region are separated from an auxiliary carrier and semiconductor bodies which are arranged outside the mounting regions remain on the auxiliary carrier.

14. An optoelectronic component comprising:
a component carrier with at least two connection pads;
a semiconductor body with a semiconductor layer sequence, at least two contact areas being provided on the semiconductor body, each contact area being electrically conductively connected to a connection pad; and
an interspace between the semiconductor body and the component carrier, the interspace being filled at least partially with a filler material.

15. The optoelectronic component according to claim 14, wherein the at least two contact areas are provided on the same side of an active region.

16. The method according to claim 2, wherein in step a) the auxiliary carrier is provided with separate semiconductor bodies, which have been preselected with regard to their optoelectronic properties.

17. The method according to claim 2 wherein the semiconductor bodies are selectively detached from the auxiliary carrier after step d).

18. The method according to claim 2, wherein the auxiliary carrier is embodied as a film.

19. The method according to claim 18, wherein, in the finished optoelectronic component, a part of the film remains on the semiconductor body.
